(19) United States
(12) Patent Application Publication
(10) Pub. No.: US 2023/0026927 A1
(43) Pub. Date: Jan. 26, 2023

(54) SiC EPITAXIAL WAFER AND METHOD FOR MANUFACTURING SiC EPITAXIAL WAFER

(71) Applicant: SHOWA DENKO K.K., Tokyo (JP)

(72) Inventors: Tsubasa SHIONO, Chichibu-shi (JP); Yuichiro MABUCHI, Chichibu-shi (JP)

(73) Assignee: SHOWA DENKO K.K., Tokyo (JP)

(21) Appl. No.: 17/862,933

(22) Filed: Jul. 12, 2022

(30) Foreign Application Priority Data
Jul. 13, 2021 (JP) 2021-115760

(51) Int. Cl. H01L 21/02; H01L 29/16; H01L 29/20

(52) U.S. Cl. CPC H01L 21/02378; H01L 21/0262; H01L 21/02529; H01L 21/0254; H01L 29/1608; H01L 29/2003

(57) ABSTRACT

A SiC epitaxial wafer includes a SiC substrate and an epitaxial layer laminated on the SiC substrate, wherein the epitaxial layer comprises a first layer, a second layer and a third layer in order from the SiC substrate side, the nitrogen concentration of the SiC substrate is 6.0×10¹⁸ cm⁻³ or more and 1.5×10¹⁹ cm⁻³ or less, the nitrogen concentration of the first layer is 1.0×10¹⁷ cm⁻³ or more and 1.5×10¹⁸ cm⁻³ or less, the nitrogen concentration of the second layer is 1.0×10¹⁸ cm⁻³ or more and 5.0×10¹⁸ cm⁻³ or less, and the nitrogen concentration of the third layer is 5.0×10¹³ cm⁻³ or more and 1.0×10¹⁷ cm⁻³ or less.

### BACKGROUND OF THE INVENTION

### Field of the Invention

The present disclosure relates to a SiC epitaxial wafer and a method of manufacturing a SiC epitaxial wafer.

Priority is claimed on Japanese Patent Application No. 2021-115760, filed on Jul. 13, 2021, the content of which is incorporated herein by reference.

### Description of Related Art

Silicon carbide (SiC) has an insulation breakdown electric field that is an order of magnitude larger than silicon (Si), a band gap that is three times larger than silicon (Si), and a thermal conductivity that is about three times higher than silicon (Si). Silicon carbide (SiC) is expected to be applied to power devices, high frequency devices, high temperature operation devices and the like.

In order to promote practical use of SiC devices, it is required to establish high-quality SiC epitaxial wafers and high-quality epitaxial growth techniques.

The SiC device is formed on a SiC epitaxial wafer. The SiC epitaxial wafer includes an SiC substrate and an epitaxial layer laminated on the SiC substrate. The SiC substrate is obtained by processing a bulk single crystal of SiC grown by a sublimation recrystallization method or the like. The epitaxial layer is formed by chemical vapor deposition (CVD) or the like, and serves as an active region of the device.

Basal plane dislocation (BPD) is known as one of device killer defects that cause fatal defects in SiC devices in SiC epitaxial wafers. For example, when a forward current is applied to the bipolar device, the stacking fault expands with the BPD as a base point, resulting in a stacking fault with high resistance. The high resistance part generated in the device reduces the reliability of the device. The BPD has a property of expanding while forming stacking faults when minority carriers recombine in the vicinity thereof

For example, Patent Literatures 1 to 3 discloses that a buffer layer containing impurities having a concentration as high as or higher than that of the substrate is formed between the SiC substrate and the semiconductor layer on which the device is formed. The buffer layer suppresses the BPD from expanding to become a stacking fault.

In the fabrication of SiC devices, the thickness of the epitaxial layer is important information. If the measured film thickness of the epitaxial layer differs from the actual film thickness, trouble may occur in the process. The film thickness of the epitaxial layer can be measured, for example, by Fourier transform infrared spectroscopy (FT-IR). FT-IR measures film thickness by Fourier transform from the interference waveform between surface reflection and interface reflection. If there are multiple interfaces, multiple interference waveforms occur. When the interference waveforms overlap each other, a desired interference waveform cannot be separated, and a desired film thickness cannot be measured. For example, if a buffer layer containing a high concentration of impurities is formed between a SiC substrate and a semiconductor layer on which a device is formed, the total thickness of the epitaxial layer may not be accurately measured.

### CITATION LIST

### Patent Literature

### Patent Literature 1

Japanese Examined Patent Application No. 6627938

### Patent Literature 2

Japanese Examined Patent Application No. 6351874

### Patent Literature 3

Japanese Examined Patent Application No. 5687422

### SUMMARY OF THE INVENTION

A first aspect of the present disclosure provides a SiC epitaxial wafer including a

SiC substrate and an epitaxial layer laminated on the SiC substrate, wherein the epitaxial layer includes a first layer, a second layer and a third layer in order from the SiC substrate side, the nitrogen concentration of the SiC substrate is 6.0×10¹⁸ cm⁻³ or more and 1.5×10¹⁹ cm⁻³ or less, the nitrogen concentration of the first layer is 1.0×10¹⁷ cm ⁻³ or more and 1.5×10¹⁸ cm⁻³ or less, the nitrogen concentration of the second layer is 1.0×10¹⁸ cm⁻³ or more and 5.0×10¹⁸cm⁻³ or less, and the nitrogen concentration of the third layer is 5.0×10¹³ cm⁻³ or more and 1.0×10¹⁷ cm⁻³ or less.

In the SiC epitaxial wafer according to the above aspect, the film thickness of the second layer may be 2.0 μm or more.

In the SiC epitaxial wafer according to the above aspect, the thickness of the first layer may be 0.2 μm or more and 2.0 μm or less.

A second aspect of the present disclosure provides method of manufacturing a SiC epitaxial wafer including a step of laminating a first layer having a nitrogen concentration of 1.0×10¹⁷ cm⁻³ or more and 1.5×10¹⁸ cm ⁻³ or less on a SiC substrate having a nitrogen concentration of 6.0×10¹⁸ cm⁻³ or more and 1.5×10¹⁹ cm⁻³ or less, a step of laminating a second layer having a nitrogen concentration of 1.0×10¹⁸ cm⁻³ or more and 5.0×10¹⁸ cm⁻³ or less on the first layer, and a step of laminating a third layer having a nitrogen concentration of 5.0×10¹³ cm⁻³ or more and 1.0×10¹⁷ cm⁻³ or less on the second layer.

### BRIEF DESCRIPTION OF THE DRAWINGS

FIG. 1 is a cross-sectional view of a SiC epitaxial wafer according to the first embodiment.

FIG. 2 is a diagram showing the measurement principle of FT-IR.

FIG. 3 is shows the FT-IR measurement results when the nitrogen concentration of each layer is not controlled (comparative example).

FIG. 4 is a schematic view of a film thickness measuring points in the SiC epitaxial wafer in the first embodiment.

### DETAILED DESCRIPTION OF THE INVENTION

Hereinafter, this embodiment will be described in detail with reference to the drawings. The drawings used in the following description may show, for convenience's sake, the features of the present disclosure in enlarged form, and the dimensional proportions of the components may be different from those in practice. The materials, dimensions, and the like exemplified in the following description are only examples, and the present disclosure is not limited thereto, and the disclosure can be carried out by appropriately changing the gist thereof without changing it.

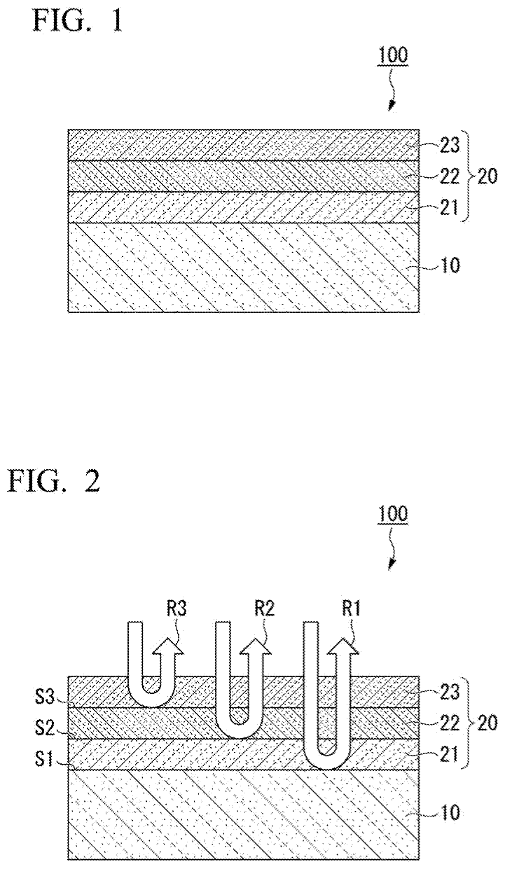

FIG. 1 is a cross-sectional view of a SiC epitaxial wafer 100 according to the first embodiment. The SiC epitaxial wafer 100 has a SiC substrate 10 and an epitaxial layer 20.

The SiC substrate 10 is cut out of a SiC ingot, for example. The SiC ingot is grown on a SiC seed crystal using, for example, a sublimation method. The SiC substrate 10 has, for example, a surface having an offset angle in the <11 -20> direction from (0001) as a growth surface.

The SiC substrate 10 is doped with impurities. The impurity is, for example, nitrogen. The nitrogen concentration of the SiC substrate 10 is 6.0×10¹⁸ cm⁻³ or more and 1.5×10¹⁹ cm⁻³ or less. The nitrogen concentration of the SiC substrate 10 is preferably 6.5×10¹⁸ cm⁻³ or more. The in-plane uniformity of the doping concentration is preferably within 30%, more preferably within 20%. The size of the SiC substrate 10 in plan view is, for example, 6 inches or larger.

The epitaxial layer 20 is laminated on the SiC substrate 10. The epitaxial layer 20 is formed by, for example, a chemical vapor deposition method (CVD method). The epitaxial layer 20 includes, for example, a first layer 21, a second layer 22, and a third layer 23. The epitaxial layer 20 is laminated on an SiC substrate 10 in the order of a first layer 21, a second layer 22, and a third layer 23. Each of the first layer 21, the second layer 22, and the third layer 23 is divided by nitrogen concentration. Each of the first layer 21, the second layer 22, and the third layer 23 may include a plurality of layers.

The first layer 21 is between the SiC substrate 10 and the second layer 22. The first layer 21 is laminated on the SiC substrate 10. The first layer 21 is an n-type or p-type semiconductor.

The first layer 21 has a lower nitrogen concentration than the SiC substrate 10 and a lower nitrogen concentration than the second layer 22. The nitrogen concentration of the first layer 21 is 1.0×10¹⁷ cm⁻³ or more and 1.5×10¹⁸ cm⁻³ or less. The nitrogen concentration of the first layer 21 is preferably 0.3 times or less of the nitrogen concentration of the SiC substrate 10, and more preferably 0.2 times or less. The in-plane uniformity of the doping concentration of the first layer 21 is preferably within 50%, more preferably within 30%.

The thickness of the first layer 21 is, for example, 0.2 μm or more and 2.0 μm or less, preferably 0.2 μm or more and less than 1.2 μm. In the FT-IR, the interference waveform accompanying the interfacial reflection between the SiC substrate 10 and the first layer 21 and the interference waveform accompanying the interfacial reflection between the first layer 21 and the second layer 22 tend to overlap. In the case of the SiC epitaxial wafer 100 according to the present embodiment, even if the thickness of the first layer 21 is small, overlap of the interference waveforms can be suppressed, and the total thickness of the epitaxial layer 20 can be accurately measured.

The first layer 21 converts BPD into TED (threading edge dislocation) at the interface between the first layer 21 and the SiC substrate 10, thereby suppressing the succession of BPD in the SiC substrate 10 to the epitaxial layer 20.

The second layer 22 is between the first layer 21 and the third layer 23. The second layer 22 is laminated on the first layer 21.

The nitrogen concentration of the second layer 22 is higher than that of the first layer 21. The second layer 22 is an n-type semiconductor layer called a high concentration layer. The second layer 22 suppresses carriers in the epitaxial layer 20 from reaching the SiC substrate 10. When the carriers reach the SiC substrate 10 and the carriers are recombined in the vicinity of the BPD in the SiC substrate 10, the stacking fault originating from the BPD expands, which increases device resistance and leads to a decrease in reliability.

The nitrogen concentration of the second layer 22 is 1.0×10¹⁸ cm⁻³ or more and 5.0×10¹⁸ cm⁻³ or less, preferably 1.0×10¹⁸ cm⁻³ or more and 3.5×10¹⁸ cm⁻³ or less. The nitrogen concentration of the second layer 22 is preferably 10 times or less of the nitrogen concentration of the first layer 21, and more preferably 5 times or less. The in-plane uniformity of the doping concentration is preferably within 50%, more preferably within 30%.

The thickness of the second layer 22 is, for example, 2.0 μm or more, preferably 10 μm or less. If the thickness of the second layer 22 is sufficiently thick, it is possible to further suppress the carriers in the epitaxial layer 20 from reaching the SiC substrate 10. If the second layer 22 is too thick, the throughput increases, causing an increase in the cost of the SiC epitaxial wafer 100.

The third layer 23 is laminated on the second layer 22. The third layer 23 is a layer in which a drift current flows and functions as a device. The third layer 23 is referred to as a drift layer. The drift current is a current generated by the flow of carriers when a voltage is applied to the semiconductor.

The third layer 23 contains impurities. The impurity is, for example, nitrogen. The nitrogen concentration of the third layer 23 is 5.0×10¹³ cm⁻³ or more and 1.0×10¹⁷ cm⁻³ or less, preferably 1.0×10¹⁴ cm' or more and 1.0×10¹⁷ cm⁻³ or less. The nitrogen concentration of the third layer 23 is preferably 0.1 times or less of the nitrogen concentration of the second layer 22, and more preferably 0.02 times or less. The in-plane uniformity of the doping concentration is preferably within 20%, more preferably within 10%.

The thickness of the third layer 23 is, for example, 5 μm or more.

The nitrogen concentration in each layer can be measured by mercury probe (Hg-CV) method, secondary ion mass spectrometry (SIMS), or the like.

In the Hg-CV method, the difference between the donor concentration Nd and the acceptor concentration Na (Nd-Na) is measured as an n-type impurity concentration. If the acceptor concentration is sufficiently small compared to the donor concentration, this concentration difference can be considered n-type impurity concentrations.

Secondary ion mass spectrometry (SIMS) is a method of performing mass spectrometry on secondary ions that have popped out while cutting a layer in the thickness direction. The doping concentration can be measured from mass spectrometry.

The measurement point of the nitrogen concentration may be any point as long as the distribution in the wafer surface can be reflected. Preferably, portions less than 5 mm from the edge of the wafer are not included in the measurement points. For example, a plurality of points are measured in the cross direction with the center of the wafer as the origin. For example, a total of 21 points consisting of 5 points arranged at equal intervals in each of the 4 directions of the cross with the origin as the center are measured. The nitrogen concentration described above is the average of the concentrations measured at each point. The concentration at each measurement point does not deviate significantly from the mean value, and at least one of the measurement points satisfies the above range of nitrogen concentrations. In-plane uniformity is the value obtained by subtracting the minimum value from the maximum value of in-plane measurements and dividing by the average value of in-plane measurements.

Next, a method of manufacturing the SiC epitaxial wafer 100 according to the first embodiment will be described. The method of manufacturing the SiC epitaxial wafer 100 includes a step of preparing an SiC substrate 10 and a step of sequentially laminating a first layer 21, a second layer 22 and a third layer 23 on the SiC substrate 10.

First, a SiC substrate 10 is prepared. The manufacturing method of the SiC substrate 10 is not particularly required. For example, it is obtained by slicing a SiC ingot obtained by a sublimation method or the like. For example, the main surface of the SiC substrate 10 is sliced so as to have an offset angle of 0.4° to 5° with respect to the (0001) surface. The SiC substrate 10 is selected from SiC substrates having an impurity concentration of 6.0×10¹⁸ cm⁻³ or more and 1.5×10¹⁹ cm⁻³ or less.

In the SiC substrate 10, BPD exists along the (0001) plane (c plane). The number of BPDs exposed on the growth surface of the SiC substrate 10 is preferably small, but is not particularly limited. For example, the number of BPDs present on the surface (growth surface) of a 6 inch SiC substrate is about 500 to 5000 per 1 cm².

Next, a first layer 21 is formed on the SiC substrate 10. The film formation of the first layer 21 is carried out by a chemical vapor deposition method by passing a source gas and a dopant gas on the SiC substrate 10. The source gas is divided into a Si-based source gas containing Si in the molecule and a C-based source gas containing C in the molecule. The dopant gas is, for example, nitrogen gas.

The nitrogen concentration of the first layer 21 is 1.0×10¹⁷ cm⁻³ or more and 1.5×10¹⁸ cm⁻³ or less. The nitrogen concentration of the first layer 21 is controlled by adjusting the C/Si ratio and the dopant gas concentration. The C/Si ratio is the molar ratio of C atoms in the C-based source gas to Si atoms in the Si-based source gas.

Next, a second layer 22 is formed on the first layer 21. The nitrogen concentration of the second layer 22 is 1.0×10¹⁸ cm⁻³ or more and 5.0×10¹⁸ cm⁻³ or less. Next, a third layer 23 is formed on the second layer 22. The nitrogen concentration of the third layer 23 is 5.0×10¹³ cm⁻³ or more and 1.0×10¹⁷ cm⁻¹ or less. The second layer 22 and the third layer 23 can be formed by the same method as the first layer 21.

In the SiC epitaxial wafer 100 according to the first embodiment, the total thickness of the epitaxial layer 20 and the thickness of the third layer 23 can be measured. The total thickness of the epitaxial layer 20 and the thickness of the third layer 23 can be measured by FT-IR.

FIG. 2 is a diagram showing the measurement principle of FT-IR. The SiC epitaxial wafer 100 has an interface S1 between the SiC substrate 10 and the first layer 21, an interface S2 between the first layer 21 and the second layer 22, and an interface S3 between the second layer 22 and the third layer 23. An interface reflection R1 is generated at the interface S1, an interface reflection R2 is generated at the interface S2, and an interface reflection R3 is generated at the interface S3. FT-IR measures the film thickness by Fourier transform from the interference waveform between the surface reflection and the respective interfacial reflection R1, R2, and R3.

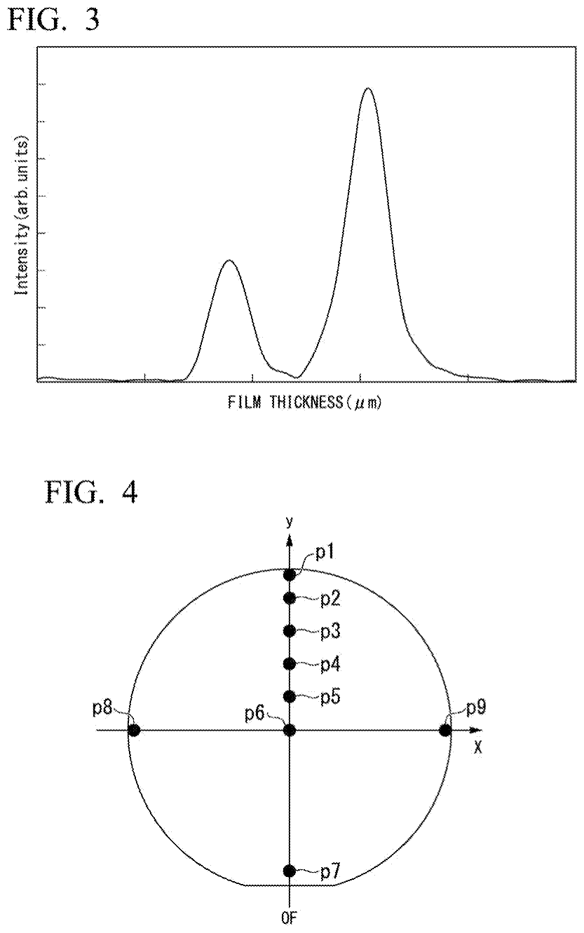

FIG. 3 shows the FT-IR measurement results when the nitrogen concentration of each layer is not controlled (comparative example). The left peak in FIG. 3 is derived from the interfacial reflection R3. The right peak in FIG. 3 is derived from interfacial reflection R1 and interfacial reflection R2. As shown in FIG. 3, the peaks derived from the interfacial reflection R1 and the peaks derived from the interfacial reflection R2 are mixed and cannot be separated. Therefore, the total thickness of the epitaxial layer 20, and the total thickness of the second layer 22 and the third layer 23 cannot be obtained separately from the measurement result of the FT-IR.

On the other hand, in the SiC epitaxial wafer 100 according to the first embodiment, the refractive index of each layer is controlled by controlling the nitrogen concentration of each layer. Therefore, the interfacial reflection R2 can be eliminated from the FT-IR measurement result, and the influence of the interfacial reflection R2 can be eliminated from the right peak in FIG. 3. Therefore, the total thickness of the epitaxial layer 20 can be measured from the peak derived from the interfacial reflection R1. The thickness of the third layer 23 can be measured simultaneously from the peak derived from the interface reflection R3.

Although preferred embodiments of the present disclosure have been described in detail above, the present disclosure is not limited to specific embodiments, and various modifications and modifications can be made within the scope of the subject matter of the present disclosure described in the claims.

### EXAMPLES

### Example 1

SiC substrates with nitrogen concentration in the range from 6.0×10¹⁸ cm⁻³ to 1.5×10¹⁹ cm⁻³ were prepared. SiC substrate size was 6 inches. A first layer, a second layer, and a third layer were sequentially laminated as epitaxial layers on the SiC substrate. The nitrogen concentration of the first layer was 1.0×10¹⁸ cm⁻³. The nitrogen concentration of layer 2 was 3.5×10¹⁸ cm⁻³. The nitrogen concentration of the layer 3 was 1.0×10¹⁶ cm^{-3.}

FIG. 4 is a schematic view of a film thickness measuring points in the SiC epitaxial wafer in Example 1. As shown in FIG. 4, the film thickness of the epitaxial layer was measured by FT-IR at each of the nine measurement points p1 to p9.

### Comparative Example 1

Comparative Example 1 differs from Example 1 only in that the nitrogen concentration of the second layer is 6.5×10¹⁸ cm⁻³. With the other conditions being the same as in Example 1, the film thickness of the epitaxial layer was measured by FT-IR at each of the nine measurement points p1 to p9.

In Example 1 and Comparative Example 1, the measured total thickness of the epitaxial layer was different. In comparison with the approximate set film thickness calculated from the growth rate, the total thickness of the epitaxial layer in Example 1 is considered to be correct. In comparison with the in-plane average value, the average value of the total thickness of the epitaxial layer measured in Comparative Example 1 was 0.2 μm different from the average value of the total thickness of the epitaxial layer measured in Example 1. In Comparative Example 1, as shown in FIG. 3, it is considered that the peaks derived from the interfacial reflection R1 and the peaks derived from the interfacial reflection R2 were mixed.

### Example 2

SiC substrates were cut out from SiC ingots with nitrogen concentration of about 7.0×10¹⁸ cm⁻³. A first layer, a second layer, and a third layer were sequentially laminated as epitaxial layers on the SiC substrate. The nitrogen concentration of the first layer was 1.0×10¹⁸ cm⁻³. The nitrogen concentration of layer 2 was 3.7×10¹⁸ cm⁻³. The nitrogen concentration of layer 3 was 1.0×10¹⁶ cm⁻³. The total thickness of the epitaxial layer at the measurement point p1 was measured by FT-IR.

### Example 3

Example 3 differs from Example 2 in that the SiC substrate was cut from a SiC ingot having a nitrogen concentration of about 7.5×10¹⁸ cm⁻³. Six SiC substrates were taken out, and epitaxial layers were formed on each SiC substrate. The configuration of each epitaxial layer was the same as in Example 2. The total thickness of the epitaxial layer at the measurement point p1 was measured by FT-IR.

### Example 4

Example 4 differs from Example 2 in that the SiC substrate was cut from another SiC ingot having a nitrogen concentration of about 6.5×10¹⁸ cm⁻³. An epitaxial layer was formed on a SiC substrate. The configuration of the epitaxial layer was the same as in Example 2. The total thickness of the epitaxial layer at the measurement point p1 was measured by FT-IR.

### Comparative Example 2

Comparative Example 2 differs from Example 2 in that the SiC substrate was cut out from a SiC ingot having a nitrogen concentration of about 5.7×10¹⁸ cm⁻³. Two SiC substrates were taken out, and epitaxial layers were formed on each SiC substrate. The configuration of each epitaxial layer was the same as in Example 2. The total thickness of the epitaxial layer at the measurement point p1 was measured by FT-IR.

### Comparative Example 3

Comparative Example 3 differs from Example 2 in that the SiC substrate was cut out from a SiC ingot having a nitrogen concentration of about 5.5×10¹⁸ cm⁻³. Four SiC substrates were taken out, and epitaxial layers were formed on each SiC substrate. The configuration of each epitaxial layer was the same as in Example 2. The total thickness of the epitaxial layer at the measurement point p1 was measured by FT-IR.

The film thickness measurement results of Example 2-4 and Comparative Examples 2 and 3 are summarized in Table 1 below. Table 1 shows the difference between the set film thickness and the measured film thickness. The difference between the set film thickness and the measured film thickness was obtained by the following relational expression. The set film thickness is calculated from the film formation conditions and the growth rate.

{(“Measured film thickness”−“Set film thickness”)/“Set film thickness”}×100 (%)

As shown in Table 1, in Example 24 in which the nitrogen concentration of the SiC substrate was 6.0×10¹⁸ cm⁻³ or more, the difference between the set film thickness and the measured film thickness was about 1%. On the other hand, in Comparative Examples 2 and 3 in which the nitrogen concentration is less than 6.0×10¹⁸ cm⁻³, there are portions in which the difference between the set film thickness and the measured film thickness is 2% or more. In Comparative Examples 2 and 3, the total thickness of the epitaxial layer was measured to be thin. In Comparative Examples 2 and 3, as shown in FIG. 3, the peaks derived from the interfacial reflection R1 and the peaks derived from the interfacial reflection R2 are mixed.

TABLE

| | | Difference between set film |
|---|---|---|
| | Concentration | thickness and measured film |
| | of Nitrogen | thickness |
| Example 2 | 7.0 × 10¹⁸ | 1% |
| Example 3 | 7.5 × 10¹⁸ | 1% |
| Comparative Example 2 | 5.7 × 10¹⁸ | −2% |
| Comparative Example 3 | 5.5 × 10¹⁸ | −3% |
| Example 4 | 6.5 × 10¹⁸ | 1% |

What is claimed is:

10. A SiC epitaxial wafer, comprising:
a SiC substrate; and,
an epitaxial layer laminated on the SiC substrate,
wherein the epitaxial layer comprises a first layer, a second layer and a third layer in order from the SiC substrate side, the nitrogen concentration of the SiC substrate is 6.0×10¹⁸ cm⁻³ or more and 1.5×10¹⁹ cm⁻³ or less, the nitrogen concentration of the first layer is 1.0×10¹⁷ cm⁻³ or more and 1.5×10¹⁸ cm⁻³ or less, the nitrogen concentration of the second layer is 1.0×10¹⁸ cm⁻³ or more and 5.0×10¹⁸ cm⁻³ or less, and the nitrogen concentration of the third layer is 5.0×10¹³ cm⁻³ or more and 1.0×10¹⁷ cm⁻³ or less.

2. The SiC epitaxial wafer according to claim 1, wherein the film thickness of the second layer is 2.0 μm or more.

3. The SiC epitaxial wafer according to claim 1, wherein the thickness of the first layer is 0.2 μm or more and 2.0 μm or less.

4. A method of manufacturing a SiC epitaxial wafer, comprising:
a step of laminating a first layer having a nitrogen concentration of 1.0×10¹⁷ cm⁻³ or more and 1.5×10¹⁸ cm⁻³ or less on a SiC substrate having a nitrogen concentration of 6.0×10¹⁸ cm⁻³ or more and 1.5×10¹⁹ cm⁻³ or less;
a step of laminating a second layer having a nitrogen concentration of 1.0×10¹⁸ cm⁻³ or more and 5.0×10¹⁸ cm⁻³ or less on the first layer; and,
a step of laminating a third layer having a nitrogen concentration of 5.0×10¹³ cm⁻³ or more and 1.0×10¹⁷ cm⁻³ or less on the second layer.
